(19) United States
(12) Patent Application Publication
(10) Pub. No.: US 2026/0313799 A1
(43) Pub. Date: Oct. 8, 2026

(54) POWER MODULES WITH VERTICAL POWER FLOW

(71) Applicant: Analog Devices International Unlimited Company, Co. Limerick (IE)

(72) Inventors: Jie Mao, Redwood City, CA (US); Ying Zhao, Andover, MA (US); Bing Ren, Shanghai (CN); Shengchang Lu, San Jose, CA (US); Lanbing Liu, San Jose, CA (US); George Anthony Serpa, San Jose, CA (US)

(21) Appl. No.: 19/352,810

(22) Filed: Oct. 8, 2025

Related U.S. Application Data
(60) Provisional application No. 63/784,477, filed on Apr. 7, 2025.

(51) Int. Cl. H05K 1/14; H05K 1/18; H05K 3/30; H05K 3/36; H05K 7/20

(52) U.S. Cl. CPC H05K 1/14; H05K 1/181; H05K 3/30; H05K 3/36; H05K 7/209; H05K 2201/1003

(57) ABSTRACT

Power modules with vertical power flow are disclosed herein. In certain embodiments, a power module includes a main circuit board, an inductor component attached to the main circuit board and including at least two inductors formed in a dielectric body, and two or more power regulation circuit boards attached to different sides of the inductor component and extending substantially perpendicular to the main circuit board to provide vertical power flow. Each power regulation circuit board includes a power semiconductor die for providing power regulation using the inductor component.

### INCORPORATION BY REFERENCE TO ANY PRIORITY APPLICATIONS

The present application claims priority to U.S. Provisional Patent Application No. 63/784,477, filed Apr. 7, 2025, and titled “POWER MODULES WITH VERTICAL POWER FLOW,” the entirety of which is hereby incorporated herein by reference.

### FIELD OF THE DISCLOSURE

Embodiments of the invention relate to electronic systems, and more particularly, to power modules for providing power regulation.

### BACKGROUND

A power module can include one or more switching regulators that operate in combination with one or more inductors to provide power regulation. For example, the switching regulator can employ switches (for instance, power transistors) coupled in series and/or parallel with an output terminal that provides an output voltage to a load through an inductor. Additionally, a controller turns the switches ON and OFF to control delivery of current pulses to the output terminal through the inductor, which converts the switched pulses into a steady load current.

A power module can include a power semiconductor die for providing power conversion or regulation. One example of a power semiconductor die includes power metal-oxide-semiconductor field-effect transistors (MOSFETs) and a driver. Such a power semiconductor die is referred to as a driver and MOSFET (DrMOS) die or integrated circuit (IC).

### SUMMARY OF THE DISCLOSURE

In one aspect, a power module includes a main circuit board, an inductor component attached to the main circuit board, and two or more power regulation circuit boards each attached to a different side of the inductor component and extending substantially perpendicular to the main circuit board to provide vertical power flow. Each power regulation circuit board includes at least one power semiconductor die.

In another aspect, a power regulation system includes a customer circuit board and a power module attached to the customer circuit board. The power module includes a main circuit board attached to the customer circuit board, an inductor component attached to the main circuit board opposite the customer circuit board, and two or more power regulation circuit boards each attached to a different side of the inductor component and extending substantially perpendicular to the main circuit board to provide vertical power flow. Each power regulation circuit board includes at least one power semiconductor die.

In another aspect, a method of power module assembly is provided. The method includes attaching a first power regulation circuit board to a first side of an inductor component and attaching a second power regulation circuit board to a second side of the inductor component, the first power regulation circuit board and the second power regulation circuit board each including at least one power semiconductor die. The method further includes attaching the inductor component including the first power regulation circuit board and the second power regulation circuit board to a main circuit board to form a power module, the first power regulation circuit board and the second power regulation circuit board extending substantially perpendicular to the main circuit board to provide vertical power flow.

### BRIEF DESCRIPTION OF THE DRAWINGS

FIG. 1A is a front perspective view of a power module according to one embodiment.

FIG. 1B is a rear perspective view of the power module of FIG. 1A.

FIG. 1C is a front perspective view of the power module of FIG. 1A attached to a customer circuit board.

FIG. 1D is a front perspective view of the inductor component of the power module of FIG. 1A.

FIG. 1E is a front perspective view of one embodiment of the metallization of the inductor component of FIG. 1D.

FIG. 1F is a rear perspective view of the metallization of the inductor component of FIG. 1D.

FIG. 2A is a front perspective view of a power module with top and bottom circuit boards and annotated to show current flow.

FIG. 2B is a front perspective view of the power module of FIG. 1A annotated to show current flow.

FIG. 3A is a front perspective view of another embodiment of metallization for an inductor component of a power module.

FIG. 3B is a rear perspective view of the metallization of the inductor component of FIG. 3A.

FIG. 4A is a front perspective view of a power module according to another embodiment.

FIG. 4B is a rear perspective view of the power module of FIG. 4A.

FIG. 5A is a front perspective view of a power module according to another embodiment.

FIG. 5B is a front perspective view of a power module according to another embodiment.

FIG. 5C is a front perspective view of an example of a two by one (2×1) array of the power module of FIG. 5A.

FIG. 5D is a front perspective view of a power module according to another embodiment.

FIG. 6A is a rear perspective view of one embodiment of a power module array.

FIG. 6B is a rear perspective view of one embodiment of a thermal cooling structure.

FIG. 6C is a rear perspective view of the power module array of FIG. 6A placed in the thermal cooling structure of FIG. 6B.

FIG. 6D is a front perspective view of the power module array of FIG. 6A placed in the thermal cooling structure of FIG. 6B.

FIG. 7A is a rear perspective view of another embodiment of a power module array.

FIG. 7B is a rear perspective view of another embodiment of a thermal cooling structure.

FIG. 7C is a rear perspective view of the power module array of FIG. 7A placed in the thermal cooling structure of FIG. 7B.

FIG. 7D is a front perspective view of the power module array of FIG. 7A placed in the thermal cooling structure of FIG. 7B.

FIG. 8A is a first portion of a method of assembling the power module of FIG. 1A according to one embodiment.

FIG. 8B is a second portion of a method of assembling the power module of FIG. 1A according to one embodiment.

FIG. 8C is a third portion of a method of assembling the power module of FIG. 1A according to one embodiment.

FIG. 8D is a fourth portion of a method of assembling the power module of FIG. 1A according to one embodiment.

FIG. 8E is a fifth portion of a method of assembling the power module of FIG. 1A according to one embodiment.

FIG. 8F is a sixth portion of a method of assembling the power module of FIG. 1A according to one embodiment.

FIG. 9 is a circuit diagram of a power module according to one embodiment.

### DETAILED DESCRIPTION OF EMBODIMENTS

The following detailed description of embodiments presents various descriptions of specific embodiments of the invention. However, the invention can be embodied in a multitude of different ways. In this description, reference is made to the drawings where like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Conventional power modules have a large footprint, particularly for power modules implemented for multi-phase power regulation. For example, a conventional power module can include a sandwich structure with a top circuit board with DrMOS die(s) on top, a bottom circuit board with pinout on bottom, and an inductor component sandwiched between the top circuit board and the bottom circuit board. However, such a power module can have a large footprint, high parasitic resistance, and/or poor thermal performance.

Power modules with vertical power flow are disclosed herein. In certain embodiments, a power module includes a main circuit board, an inductor component attached to the main circuit board and including at least two inductors formed in a dielectric body, and two or more power regulation circuit boards attached to different sides of the inductor component and extending substantially perpendicular to the main circuit board to provide vertical power flow. Each power regulation circuit board includes a power semiconductor die for providing power regulation using the inductor component.

The power semiconductor dies can be DrMOS dies, or other types of power ICs with or without drivers. For example, such power semiconductor dies can include power transistors fabricated using silicon (Si), silicon carbide (SiC), gallium nitride (GaN), or other suitable power transistor processes.

In certain implementations, a heat sink is placed on top of the inductor component (for example, opposite the main circuit board attached to a bottom of the inductor component). Such a heat sink serves to extract heat out from the module effectively.

The number of power regulation circuit boards attached to the inductor component and the number of inductors in the inductor component can be selected to provide a desired number of phases for power regulation. For instance, to provide a four-phase (4-phase) power module, four inductors can be included in the inductor component, and a desired configuration of power regulation circuit boards and power semiconductor dies can be included to regulate the currents through the four inductors. In one example, two power regulation circuit boards each including two power semiconductor dies are used to regulate the currents through the four inductors. In another example, four power regulation circuit boards each including one power semiconductor die are used to regulate the currents through the four inductors.

In certain implementations, the power regulation circuit boards are attached at an angle between 80° to 100° relative to a surface of the main circuit board.

By implementing the power regulation circuit boards to be substantially perpendicular to the main circuit board, a compact power module for multi-phase power regulation is achieved. Furthermore, substantially perpendicular power regulation circuit boards allow for vertical power flow to enable higher power density, improved power regulation, and/or superior thermal performance.

In some implementations, the main circuit board is attached to a bottom of the inductor component, and a heat sink is placed on a top of the inductor component.

The inductor component can include a dielectric body (for example, a ferrite core) and at least two inductors (for instance, copper windings) that extend through the dielectric body. In certain implementations, one end of each inductor is electrically connected to a corresponding output of a power semiconductor die (for example, an output of a switching regulator of a DrMOS die) while a second end of the inductor is electrically connected to a corresponding terminal on the main circuit board. The main circuit board in turn can include a pinout on the bottom for attaching to a customer circuit board.

In some implementations, the dielectric body is shaped as a rectangular prism that includes a bottom surface for attaching to a main circuit board, a top surface for attaching to a heat sink, and four sides for attaching to a desired number of power regulation circuit boards. Although the dielectric body can be shaped in this manner, other shapes of the dielectric body are possible. For example, possible shapes of the dielectric body include polygon prisms having faces with four or more sides, for instance, a rectangular prism, a pentagonal prism, hexagonal prism, or an octagonal prism. By including more than four sides, further surfaces for attaching power regulation circuit boards are provided. Thus, the number of side walls of the inductor component that include power regulation circuit boards is flexible with design, such as 2, 3, 4, 5, or 6 or more.

In certain implementations, multiple power modules are arrayed to provide additional phases for a power regulation system. For example, two or more 4-phase power modules can be arrayed on a customer circuit board to provide 8 or more phases for power regulation.

In addition to including at least one power semiconductor die (for instance, a DrMOS die), the power regulation circuit boards can include various components attached to the power regulation circuit board using surface mount technology (SMT). Such SMT components include, but are not limited to, passive components such as capacitors.

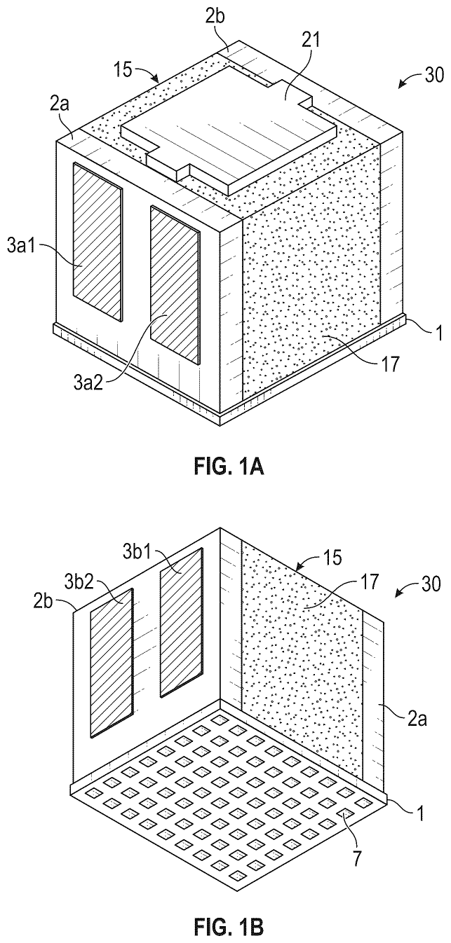

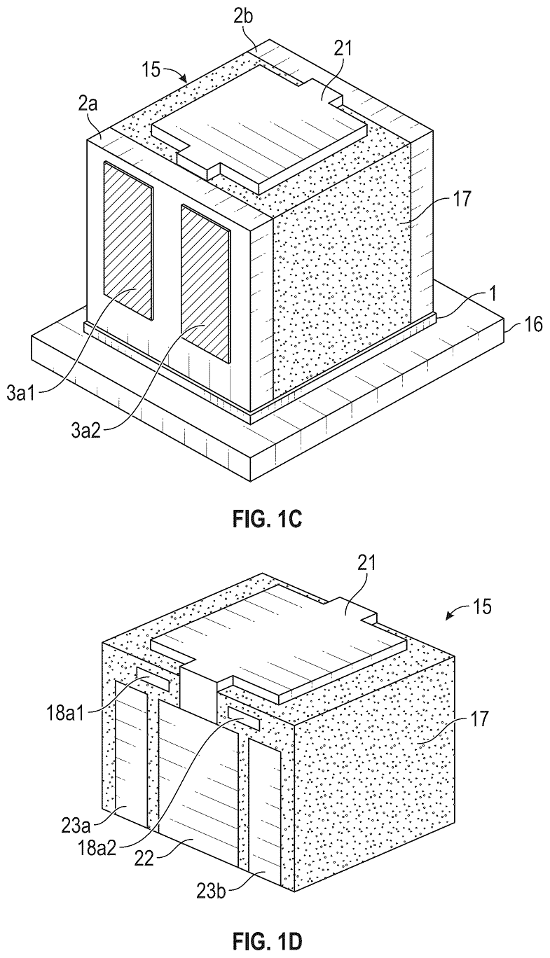

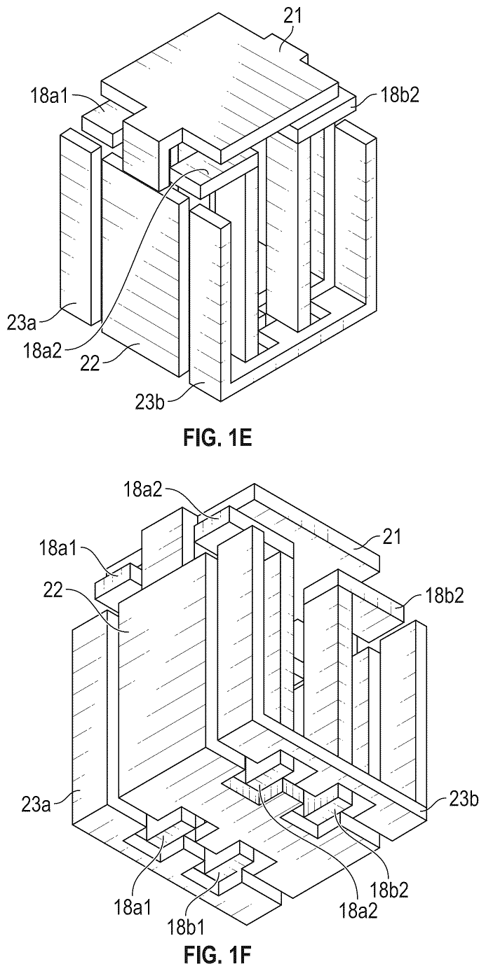

FIG. 1A is a front perspective view of a power module 30 according to one embodiment. FIG. 1B is a rear perspective view of the power module 30 of FIG. 1A. FIG. 1C is a front perspective view of the power module 30 of FIG. 1A attached to a customer circuit board 16.

With reference to FIGS. 1A-1C, the power module 30 includes a main circuit board 1, an inductor component 15, a first power regulation circuit board 2a, and a second power regulation circuit board 2b.

In the illustrated embodiment, a bottom surface of the inductor component 15 is attached to a top surface of the main circuit board 1. Additionally, a bottom surface of the main circuit board 1 includes pins 7 that form a pinout for providing electrical connections to the customer circuit board 16.

As shown in FIGS. 1A-1C, the first power regulation circuit board 2a is attached to a first side surface of the inductor component 15, while the second power regulation circuit board 2b is attached to a second side surface of the inductor component 15 opposite the first side surface. The power regulation circuit boards 2a/2b are attached at an angle of about 90° relative to the top surface of the main circuit board 1. By implementing the power regulation circuit boards 2a/2b in this manner, a compact form factor is achieved.

Each of the power regulation circuit boards 2a/2b includes two power semiconductor dies (such as DrMOS dies, power MOSFET dies, GaN dies, and/or SiC dies), in this embodiment. For example, in the illustrated embodiment, the first power regulation circuit board 2a includes a first DrMOS die 3a1 and a second DrMOS die 3a2, while the second power regulation circuit board 2b includes a third DrMOS die 3b1 and a fourth DrMOS die 3b2. Each power semiconductor die includes at least one power transistor. Although not shown in FIGS. 1A-1C, the power regulation circuit boards 2a/2b can also include various surface mount components (including, but not limited to, passive components such as capacitors) and/or additional semiconductor die(s) as desired for a particular application. The power modules herein can include semiconductor power dies that are molded with, embedded on, and/or otherwise attached to a power regulation circuit board, with or without surface mount components included.

FIG. 1D is a front perspective view of the inductor component 15 of the power module 30 of FIG. 1A. FIG. 1E is a front perspective view of one embodiment of the metallization of the inductor component 15 of FIG. 1D. FIG. 1F is a rear perspective view of the metallization of the inductor component 15 of FIG. 1D.

As shown in FIGS. 1D to 1F, the inductor component 15 includes a dielectric body 17 (for example, a ferrite core) as well as four inductors 18a1/18a2/18b1/18b2 through the dielectric body 17. In certain implementations, the inductors 18a1/18a2/18b1/18b2 correspond to copper windings formed through the dielectric body 17.

In the illustrated embodiment, the metallization of the inductor component 15 also includes ground metallization 22, first input voltage metallization 23a, second input voltage metallization 23b, and thermal cooling metallization 21 (which is also electrically grounded, in this example). In certain implementations, such metallization is implemented as part of a metal lead frame. The first input voltage metallization 23a and the second input metallization 23b carry input voltage(s) used by the power semiconductor dies for power regulation.

The thermal cooling metallization 21 provides metal at the top surface of the inductor component 15. The thermal cooling metallization 21 can be connected to a thermal cooling structure, such as a heat sink and/or cold plate. The thermal cooling metallization 21 is also electrically and thermally connected to the ground metallization 22 along the first side and the second side of the inductor component 15, and thus a thermal pathway is provided between the DrMOS dies 3a1/3a2/3b1/3b2 on the power regulation circuit boards 2a/2b and the thermal cooling metallization 21.

The power modules herein include power semiconductor dies and inductors that can be cooled together or individually, based on a desired implementation.

With reference to FIGS. 1A to 1F, the DrMOS dies 3a1/3a2/3b1/3b2 serve to regulate a current through a corresponding inductor 18a1/18a2/18b1/18b2 of the inductor component 15.

For example, an output of the first DrMOS die 3a1 is electrically connected to a first end of first inductor 18a1 near the top of the first side surface of the inductor component 15, while a second end of the first inductor 18a1 on the bottom surface of the inductor component 15 is electrically connected to a corresponding terminal of the main circuit board 1. Additionally, an output of the second DrMOS die 3a2 is electrically connected to a first end of second inductor 18a2 near the top of the first side surface of the inductor component 15, while a second end of the second inductor 18a2 on the bottom surface of the inductor component 15 is electrically connected to a corresponding terminal of the main circuit board 1. Furthermore, an output of the third DrMOS die 3b1 is electrically connected to a first end of the third inductor 18b1 near the top of the second side surface of the inductor component 15, while a second end of the third inductor 18b1 on the bottom surface of the inductor component 15 is electrically connected to a corresponding terminal of the main circuit board 1. Additionally, an output of the fourth DrMOS die 3b2 is electrically connected to a first end of fourth inductor 18b2 near the top of the second side surface of the inductor component 15, while a second end of the fourth inductor 18b2 on the bottom surface of the inductor component 15 is electrically connected to a corresponding terminal of the main circuit board 1.

Although the power module 30 depicts an example of a four-phase power module, the teachings herein are applicable to power modules with a different number of phases.

The inductors 18a1/18a2/18b1/18b2 can be electromagnetically coupled or electromagnetically uncoupled from one another based on implementation of the inductor component 15. For example, for applications in which electromagnetically coupling is desired, the inductor component 15 can be implemented to provide the inductors 18a1/18a2/18b1/18b2 with a particular value of mutual inductance to achieve a strength of magnetic coupling desired for a given application.

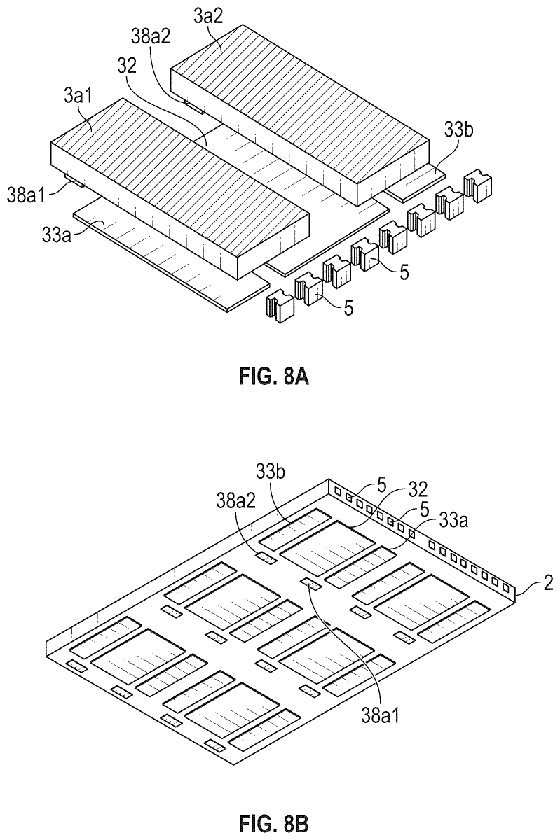

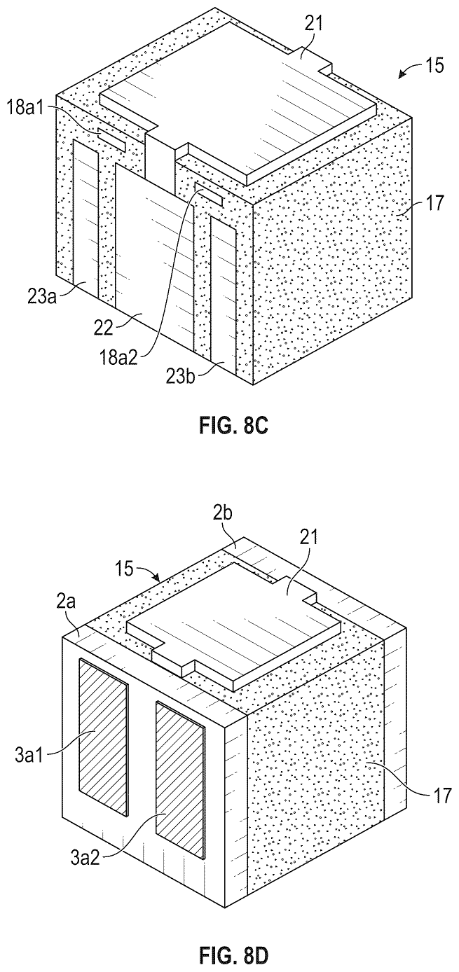

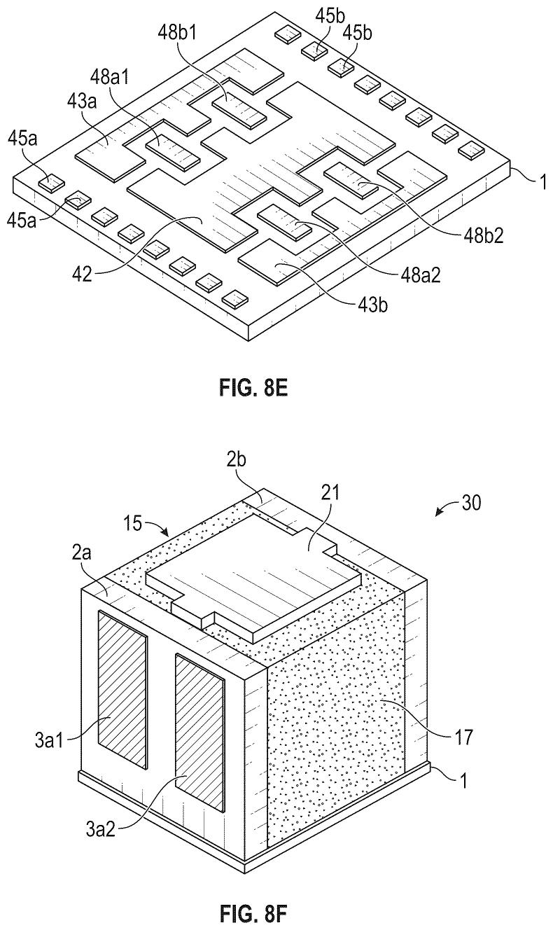

With continuing reference to FIGS. 1A-1C, a bottom edge of the first power regulation circuit board 2a and a bottom edge of the second power regulation circuit board 2b each attach to the main circuit board 1. The attachment at the bottom edge provides not only physical attachment but also electrical connectivity for providing power, ground, signals, and/or any other desired electrical connectivity. For example, the main circuit board 1 can include electrical conductors (for example, conductors 45a/45b shown in FIG. 8E) for providing electrical connections to corresponding edge conductors (for example, edge conductors 5 shown in FIG. 8A). The attachment of the bottom surface of the inductor component 15 to the main circuit board 1 also provides not only physical attachment but also electrical connectivity. For example, metallization on the bottom surface of the inductor component 15 (for example, metal regions 18a1/18a2/18b1/18b2/22/23a/23b shown in FIG. 1F) can connect to corresponding metallization on the main circuit board 1 (for example, metal regions 48a1/48a2/48b1/48b2/42/43a/43b shown in FIG. 8E).

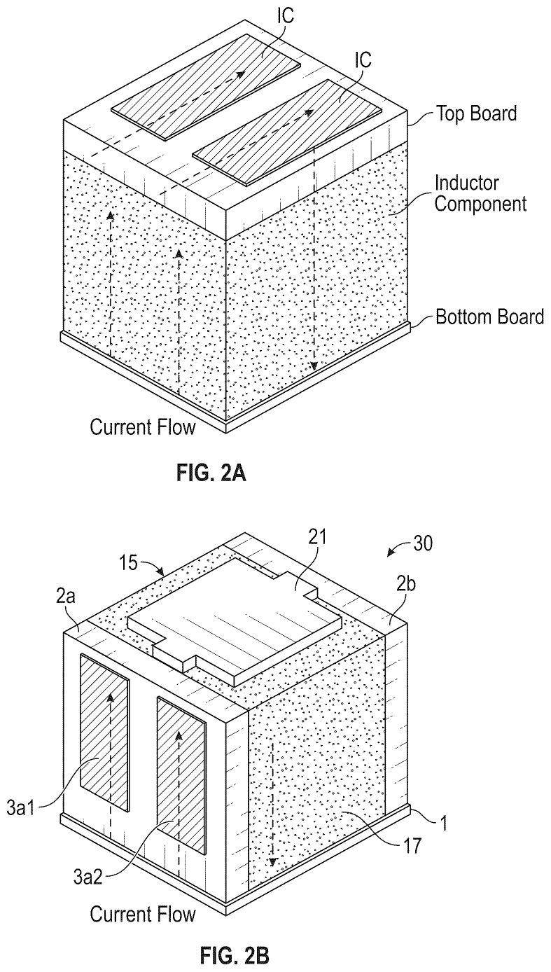

FIG. 2A is a front perspective view of a power module with top and bottom circuit boards and annotated to show current flow. As shown in FIG. 2A, the power module includes a top circuit board on which power regulation dies or ICs are attached, a bottom circuit board for attachment to a customer circuit board, and an inductor component sandwiched between the top circuit board and the bottom circuit board.

During operation, current flows vertically up from the bottom circuit board to the power regulation ICs through the inductor component, then laterally through the power regulation ICs, and then back down to the bottom circuit board.

With respect to the current path of FIG. 2A, the current path is long due to the lateral current path as well as vertical current paths that extend all the way up to the power regulation ICs on top of the top circuit board. Furthermore, all of the power regulation ICs are on a single circuit board that sets the footprint of the power module on a customer circuit board.

FIG. 2B is a front perspective view of the power module 30 of FIG. 1A annotated to show current flow. The power module 30 operates with substantially no lateral current flow. Rather, current flows vertically from the main circuit board 1 to the DrMOS dies (and thus less than a full length of the power regulation circuit boards 2a/2b), and thereafter back down to the main circuit board 1 through the inductor component 15.

Providing a major power flow path that is only vertical provides a more compact power module, higher power density, improved power regulation (for instance, higher efficiency to provide energy savings), and/or superior thermal performance. Better thermal performance in turn enables a small cooling system, which is particularly beneficial for data center applications in which water-cooling systems can be expensive and large.

In comparison to the power module of FIG. 2A, the power module 30 of FIG. 2B has IC footprint that can exceed the power module's footprint. Thus, the power module 30 of FIG. 2B is highly compact.

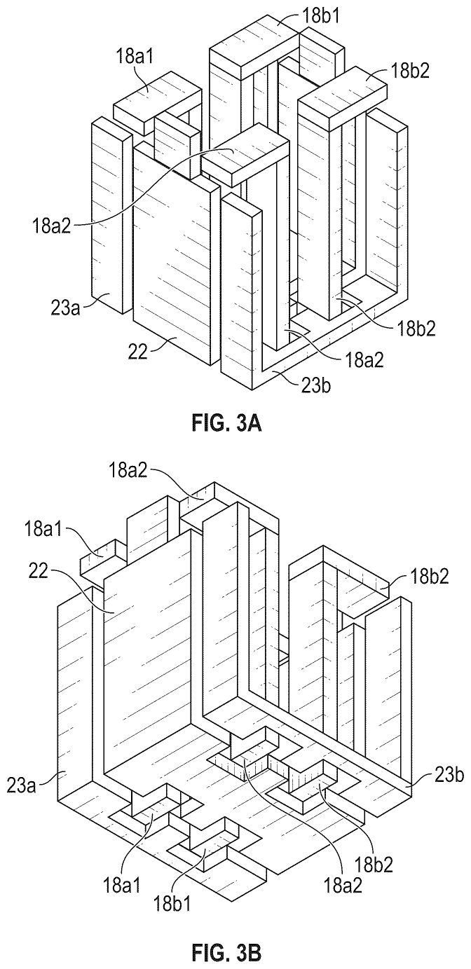

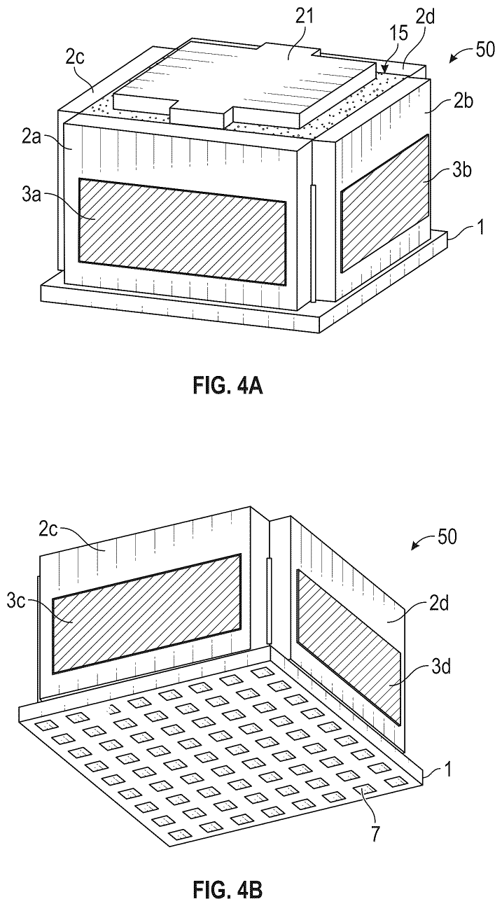

FIG. 3A is a front perspective view of another embodiment of metallization for an inductor component of a power module. FIG. 3B is a rear perspective view of the metallization of the inductor component of FIG. 3A.

In the illustrated embodiment, the metallization includes four inductors 18a1/18a2/18b1/18b2, ground metallization 22, first input voltage metallization 23a, and second input voltage metallization 23b. The inductor component metallization of FIGS. 3A-3B is similar to the inductor component metallization of FIGS. 1E-1F, except that the inductor component metallization of FIGS. 3A-3B omits the thermal cooling metallization 21.

The inductor components herein can be implemented in a wide variety of ways and can include any suitable implementation of metallization as desired for a particular application.

FIG. 4A is a front perspective view of a power module 50 according to another embodiment. FIG. 4B is a rear perspective view of the power module 50 of FIG. 4A.

The power module 50 includes a main circuit board 1, an inductor component 15, a first power regulation circuit board 2a, a second power regulation circuit board 2b, a third power regulation circuit board 2c, and a fourth power regulation circuit board 2d.

In the illustrated embodiment, a bottom surface of the inductor component 15 is attached to a top surface of the main circuit board 1. Additionally, a bottom surface of the main circuit board 1 includes pins 7 that form a pinout for providing electrical connections to the customer circuit board 16.

As shown in FIGS. 4A-4B, the first power regulation circuit board 2a is attached to a first side surface of the inductor component 15, the second power regulation circuit board 2b is attached to a second side surface of the inductor component 15, the third power regulation circuit board 2c is attached to a third side surface of the inductor component 15, and the fourth power regulation circuit board 2d is attached to a fourth side surface of the inductor component 15. The power regulation circuit boards 2a-2d are attached at an angle of about 90° relative to the top surface of the main circuit board 1.

In the illustrated embodiment, each of the power regulation circuit boards 2a-2d includes one power semiconductor die (such as a DrMOS die) for regulating current through a corresponding inductor of the inductor component 15. For example, the first power regulation circuit board 2a includes a first DrMOS die 3a for providing regulation of a current through a first inductor of the inductor component 15, the second power regulation circuit board 2b includes a second DrMOS die 3b for providing regulation of a current through a second inductor of the inductor component 15, the third power regulation circuit board 2c includes a third DrMOS die 3c for providing regulation of a current through a third inductor of the inductor component 15, and the fourth power regulation circuit board 2d includes a fourth DrMOS die 3d for providing regulation of a current through a fourth inductor of the inductor component 15.

The metallization of the inductor component 15 of FIGS. 4A-4B is implemented such that each of the four inductors connects between a corresponding one of the power regulation circuit boards 2a-2d and the main circuit board 1.

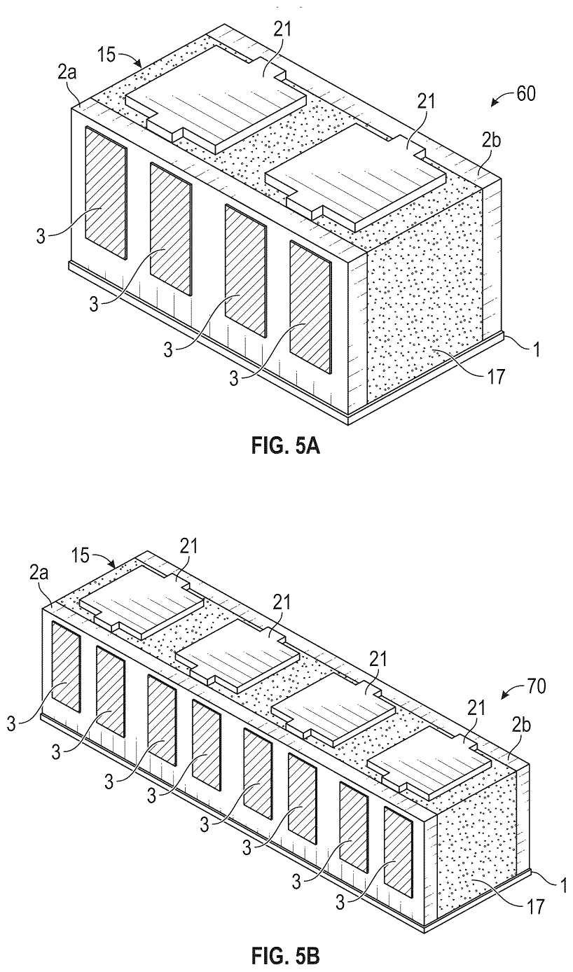

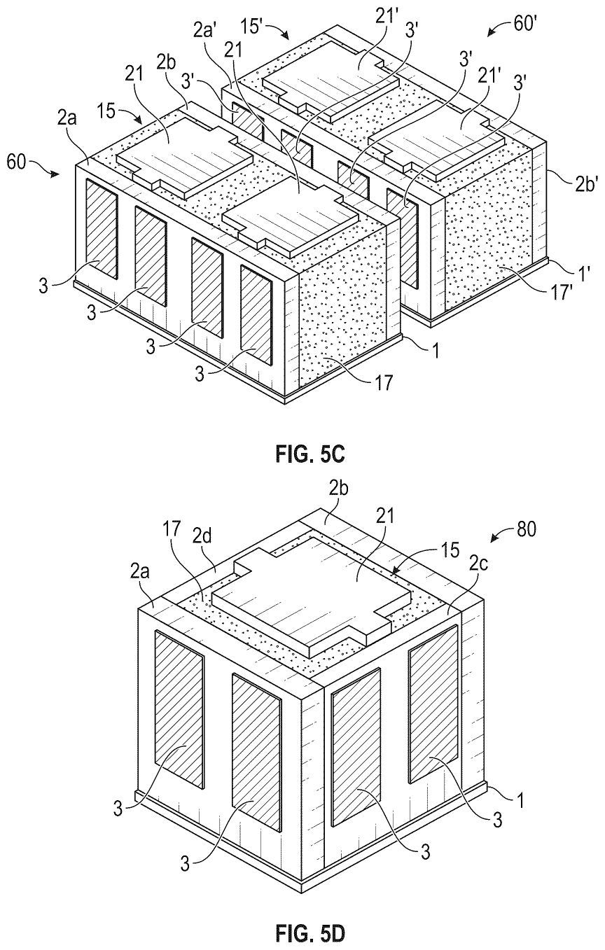

FIG. 5A is a front perspective view of a power module 60 according to another embodiment. The power module 60 includes a main circuit board 1, an inductor component 15 having a bottom surface attached to a top surface of the main circuit board 1, a first power regulation circuit board 2a attached to a first side surface of the inductor component 15, and a second power regulation circuit board 2b attached to a second side surface of the inductor component 15 opposite the first side surface.

The power module 60 of FIG. 5A is similar to the power module 30 of FIGS. 1A-1C, except that the power module 60 of FIG. 5A includes four DrMOS dies 3 on each of the first power regulation circuit board 2a and the second power regulation circuit board 2b. Thus, eight total DrMOS dies 3 are included to provide regulation to eight corresponding inductors in the inductor component 15. Thus, the power module 60 of FIG. 5A is an eight-phase (8-phase) power module.

FIG. 5B is a front perspective view of a power module 70 according to another embodiment. The power module 70 includes a main circuit board 1, an inductor component 15 having a bottom surface attached to a top surface of the main circuit board 1, a first power regulation circuit board 2a attached to a first side surface of the inductor component 15, and a second power regulation circuit board 2b attached to a second side surface of the inductor component 15 opposite the first side surface.

The power module 70 of FIG. 5B is similar to the power module 30 of FIGS. 1A-1C, except that the power module 70 of FIG. 5B includes eight DrMOS dies 3 on each of the first power regulation circuit board 2a and the second power regulation circuit board 2b. Thus, sixteen total DrMOS dies 3 are included to provide regulation to sixteen corresponding inductors in the inductor component 15. Thus, the power module 70 of FIG. 5B is a sixteen-phase (16-phase) power module.

FIG. 5C is a front perspective view of an example of a 2×1 array of the power module 60 of FIG. 5A. Thus, a first power module 60 (including a main circuit board 1, an inductor component 15, a first power regulation circuit board 2a, and a second power regulation circuit board 2b) is placed alongside a second power module 60′ (including a main circuit board 1′, an inductor component 15′, a first power regulation circuit board 2a′, and a second power regulation circuit board 2b′) to form a 2×1 array of power modules. The inductor component 15 includes a first set of eight inductors within the dielectric body 17, while the inductor component 15′ includes a second set of eight inductors within the dielectric body 17′. Eight DrMOS dies 3 on the circuit boards 2a/2b provide regulation to the first set of eight inductors, while eight DrMOS dies 3′ provide regulation to the second set of eight inductors. Thermal cooling metallization structures 21/21′ are included in this example to aid in providing attachment to a thermal cooling structure for enhanced thermal performance.

By arraying power modules, a desired total number of phases can be achieved. For example, a 2×1 array of two 8-phase power modules (as shown in FIG. 5C) provides 16 total phases of power regulation.

Although an example with two power modules is depicted, any number of power modules can be included in an array.

FIG. 5D is a front perspective view of a power module 80 according to another embodiment. The power module 80 includes a main circuit board 1, an inductor component 15 having a bottom surface attached to a top surface of the main circuit board 1, a first power regulation circuit board 2a attached to a first side surface of the inductor component 15, a second power regulation circuit board 2b attached to a second side surface of the inductor component 15 opposite the first side surface, a third power regulation circuit board 2c attached to a third side surface of the inductor component 15, and a fourth power regulation circuit board 2d attached to a fourth side surface of the inductor component 15 opposite the third side surface.

The power module 80 of FIG. 5D is similar to the power module 30 of FIGS. 1A-1C, except that the power module 80 of FIG. 5D includes four power regulation circuit boards 2a-2d each including two DrMOS dies 3. Additionally, the inductor component 15 is implemented to include eight inductors each of which is regulated by a corresponding one of the DrMOS dies 3.

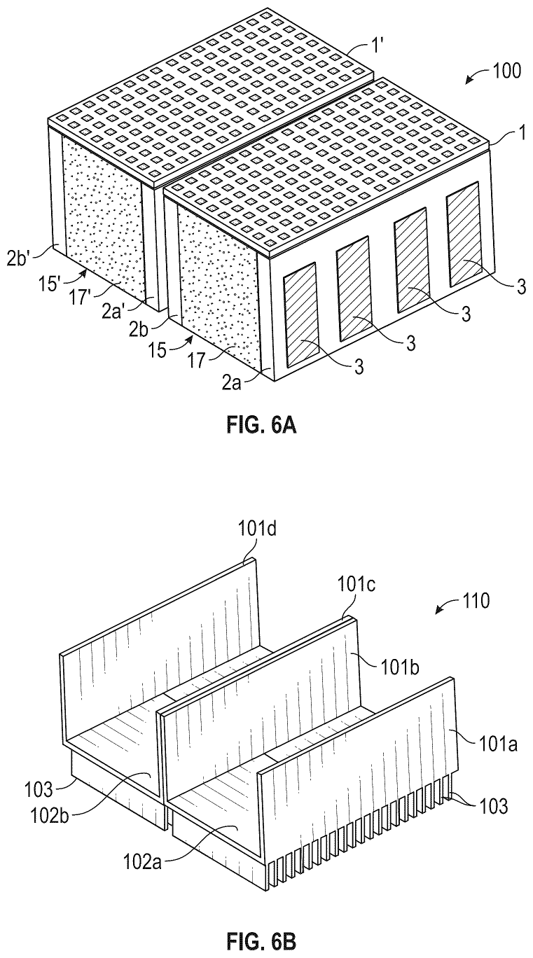

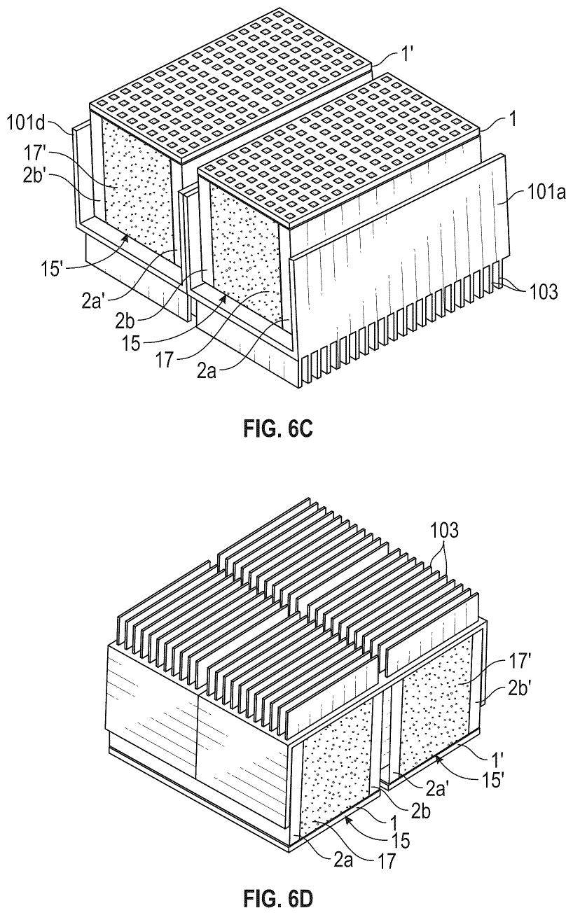

FIG. 6A is a rear perspective view of one embodiment of a power module array 100. The power module array 100 is implemented as a 2×1 array similar to that of FIG. 5C.

FIG. 6B is a rear perspective view of one embodiment of a thermal cooling structure 110. The thermal cooling structure 110 includes a first staple-shaped structure including a first base plate 102a, a first side plate 101a, and a second side plate 101b. The thermal cooling structure 110 further includes a second staple-shaped structure including a second base plate 102b, a third side plate 101c, and a fourth side plate 101d. The first staple-shaped structure is placed alongside the second staple-shaped structure with the second side plate 101b contacting the third side plate 101c.

As shown in FIG. 6B, the side plates 101a-101d extend away from the base plates 102a/102b. The thermal cooling structure 110 further includes heat fins 103 extending away from the base plates 102a/102b in a second direction opposite the first direction. Thus, the heat fins 103 have an inverted fin structure, in this embodiment.

FIG. 6C is a rear perspective view of the power module array 100 of FIG. 6A placed in the thermal cooling structure 110 of FIG. 6B. FIG. 6D is a front perspective view of the power module array 100 of FIG. 6A placed in the thermal cooling structure 110 of FIG. 6B.

With reference to FIGS. 6C-6D, the DrMOS dies 3 of each of the power regulation circuit boards 2a/2b/2a′/2b′ are in thermal contact with side plates 101a/101b/101c/101d, respectively. Furthermore, in implementations in which thermal cooling metallization 21/21′ is included for the inductor components 15/15′ (see for example, FIG. 5C), the thermal cooling metallization 21/21′ is in thermal contact with the bottom plates 102a/102b.

By including thermal cooling structure 110, enhanced thermal performance can be achieved. The thermal cooling structure 110 can operate using air cooling, water cooling, and/or immersion cooling.

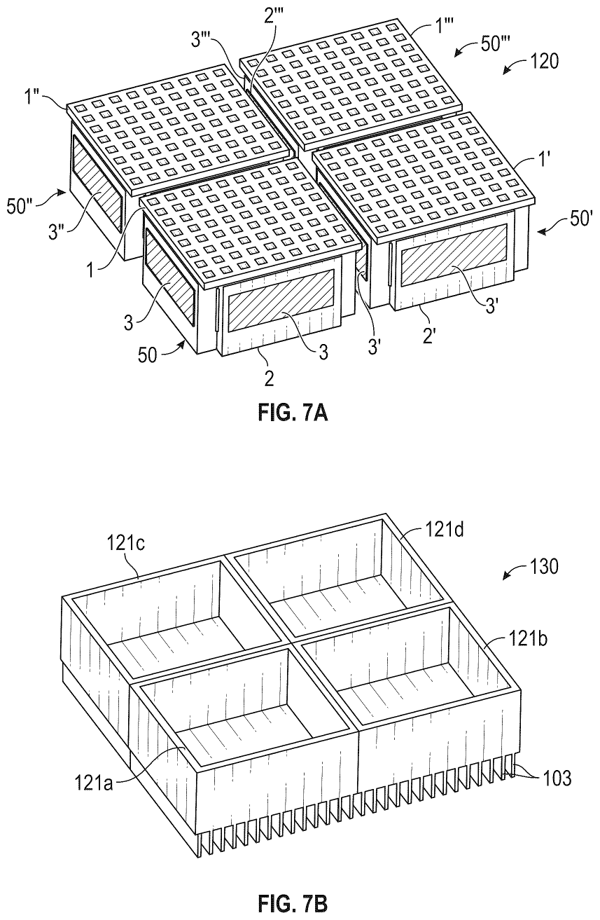

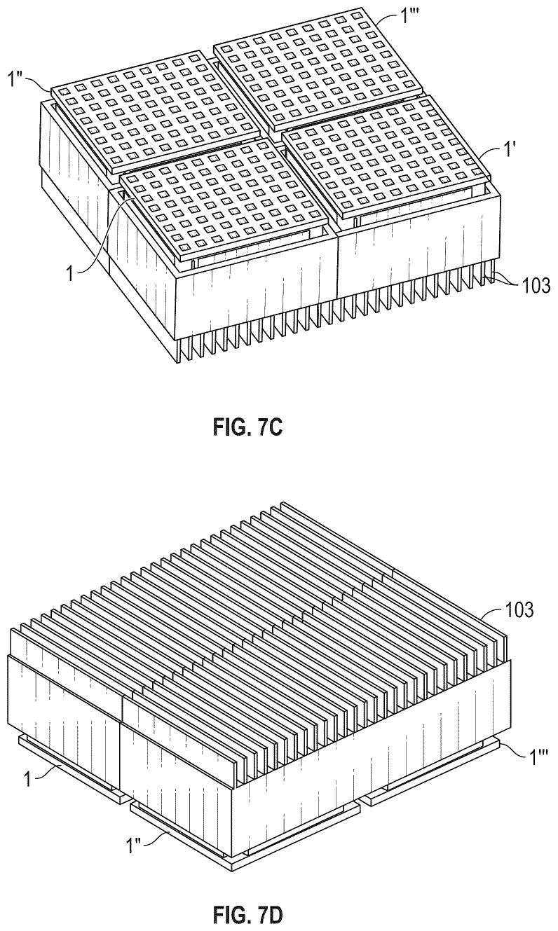

FIG. 7A is a rear perspective view of another embodiment of a power module array 120. The power module array 120 includes a two-by-two (2×2) array of power modules each similar to the power module 50 of FIGS. 4A-4B. A first power module 50 includes a main circuit board 1, an inductor component (not visible in FIG. 7A), four power regulation circuit boards 2 attached to different sides of the inductor component, and four DrMOS dies 3. Additionally, a second power module 50′ includes a main circuit board 1′, an inductor component (not visible in FIG. 7A), four power regulation circuit boards 2′ attached to different sides of the inductor component, and four DrMOS dies 3′. Furthermore, a third power module 50″ includes a main circuit board 1″, an inductor component (not visible in FIG. 7A), four power regulation circuit boards 2″ attached to different sides of the inductor component, and four DrMOS dies 3″. Additionally, a fourth power module 50″′ includes a main circuit board 1″′, an inductor component (not visible in FIG. 7A), four power regulation circuit boards 2″′ attached to different sides of the inductor component, and four DrMOS dies 3″′.

FIG. 7B is a rear perspective view of another embodiment of a thermal cooling structure 130. The thermal cooling structure 130 is implemented with a tray structure including a first section 121a for a first power module, a second section 121b for a second power module, a third section 121c for a third power module, and a fourth section 121d for a fourth power module. The thermal cooling structure 130 further includes fins 103.

FIG. 7C is a rear perspective view of the power module array 120 of FIG. 7A placed in the thermal cooling structure 130 of FIG. 7B. FIG. 7D is a front perspective view of the power module array 120 of FIG. 7A placed in the thermal cooling structure 130 of FIG. 7B.

With reference to FIGS. 7C-7D, the DrMOS dies 3/3′/3″/3″′ of each of the power regulation circuit boards 2/2′/2″/2″′ are in thermal contact with the sides of each of the sections 121a-121d of the thermal cooling structure 130. Accordingly, heat can be drawn from the dies and superior thermal performance can be achieved.

The thermal cooling structure 120 can operate using air cooling, water cooling, and/or immersion cooling.

FIG. 8A is a first portion of a method of assembling the power module 30 of FIG. 1A according to one embodiment.

With reference to FIGS. 1A-1F and 8A, various DrMOS dies 3a1/3a2 and conductors are gathered for assembly onto a substrate. The conductors include inductor connection conductors 38a1/38a2 for electrically connecting the regulation outputs of the DrMOS dies 3a 1/3a2 to respective inductors 18a1/18a2 of the inductor component 15. The conductors include a ground conductor 32 for electrically connecting to ground metallization 22, a first input voltage conductor 33a for electrically connecting to first input voltage metallization 23a, and a second input voltage conductor 33b for electrically connecting to second input voltage metallization 23b. The conductors further include edge conductors 5, which can be implemented as edge pins or build-in vias for providing electrical edge connection to the main circuit board 1 of the power module 30.

Although various components for one power regulation circuit board are shown in FIG. 8A, components for many power regulation circuit boards can be obtained at this stage.

FIG. 8B is a second portion of a method of assembling the power module 30 of FIG. 1A according to one embodiment.

In FIG. 8B, the assembled electrical components of FIG. 8A have been molded together as a molded IC strip.

FIG. 8C is a third portion of a method of assembling the power module 30 of FIG. 1A according to one embodiment.

In FIG. 8C, an inductor component 15 includes integrated inductors 18a1/18a2 and lead frame metallization 21/22/23a/23b has been obtained. Although one inductor component 15 is shown in FIG. 8C, many instantiations of the power module 30 can be obtained at this stage.

FIG. 8D is a fourth portion of a method of assembling the power module 30 of FIG. 1A according to one embodiment.

In FIG. 8D, the molded IC strip of FIG. 8B has been singulated to form many power regulation circuit boards that each include DrMOS dies, which are then attached to inductor components. For example, FIG. 8D depicts attachment of the first power regulation circuit board 2a to a first side of the inductor component 15 and attachment of the second power regulation circuit board 2b to a second side of the inductor component 15 opposite the first side. Such attachment can be made using any suitable adhesive.

FIG. 8E is a fifth portion of a method of assembling the power module 30 of FIG. 1A according to one embodiment.

In FIG. 8E, a main circuit board 1 is formed. Such a main circuit board can be formed as part of a batch strip process.

With reference to FIGS. 1A-1F and 8E, the main circuit board 1 includes various conductors including a first set of conductors 45a for providing electrical connections to an edge of the first power regulation circuit board 2a, a second set of conductors 45b for providing electrical connections to an edge of the second power regulation circuit board 2b, inductor conductors 48a1/48a2/48b1/48b2 for providing electrical connections to ends of the inductors 18a1/18a2/18b1/18b2, a ground conductor 42 for providing electrical connection to the ground metallization 22, a first input voltage conductor 43a for providing electrical connection to the first input voltage metallization 23a, and a second input voltage conductor 43b for providing electrical connection to the second input voltage metallization 23b.

FIG. 8F is a sixth portion of a method of assembling the power module 30 of FIG. 1A according to one embodiment. In FIG. 8F, assembly of FIG. 8D is attached to the main circuit board 1 to form a completed power module 30. Such assembly can include attaching various assemblies of FIG. 8D to a batch strip of main circuit boards using any suitable adhesive, and thereafter singulating to form stand-alone power modules.

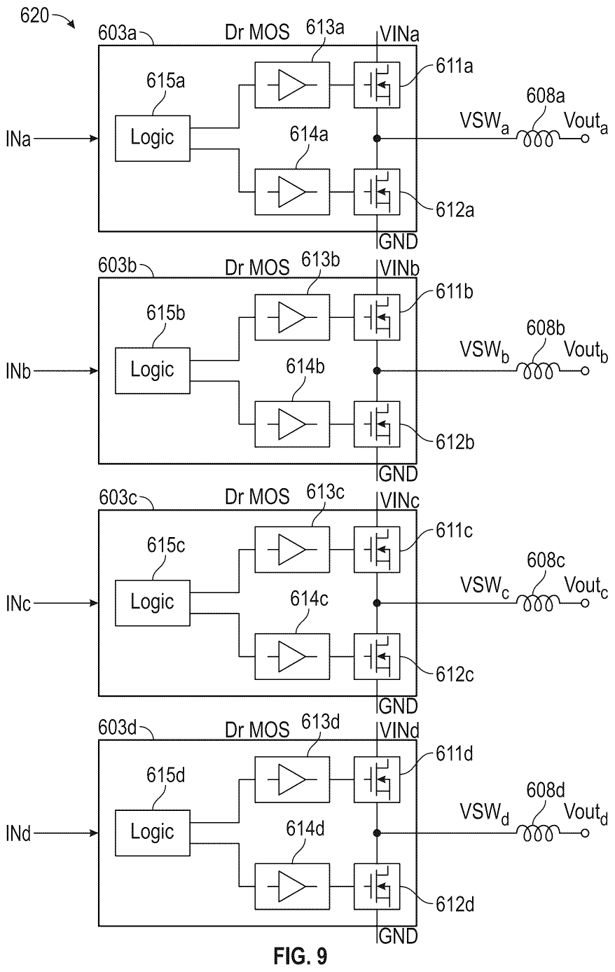

FIG. 9 is a circuit diagram of a power module 620 according to one embodiment. The power module 620 includes a first DrMOS die 603a, a first inductor 608a, a second DrMOS die 603b, a second inductor 608b, a third DrMOS die 603c, a third inductor 608c, a fourth DrMOS die 603d, and a fourth inductor 608d. Although an example of a 4-phase power module with four DrMOS dies and four inductors is depicted, any number of DrMOS dies and inductors can be included as needed for a particular application.

In the illustrated embodiment, each DrMOS die 603a/603b/603c/603d includes various MOSFET power switches as well as drivers for controlling the MOSFET power switches.

For example, the first DrMOS die 603a includes a high side power MOSFET 611a (receiving input voltage VINa), a low side power MOSFET 612a (receiving ground voltage GND), a high side driver 613a, a low side driver 614a, and a driver logic circuit 615a. Additionally, the second DrMOS die 603b includes a high side power MOSFET 611b (receiving input voltage VINb), a low side power MOSFET 612b (receiving ground voltage GND), a high side driver 613b, a low side driver 614b, and a driver logic circuit 615b. Furthermore, the third DrMOS die 603c includes a high side power MOSFET 611c (receiving input voltage VINc), a low side power MOSFET 612c (receiving ground voltage GND), a high side driver 613c, a low side driver 614c, and a driver logic circuit 615c. Additionally, the fourth DrMOS die 603d includes a high side power MOSFET 611d (receiving input voltage VINd), a low side power MOSFET 612d (receiving ground voltage GND), a high side driver 613d, a low side driver 614d, and a driver logic circuit 615d.

Although one example of a DrMOS die is shown, DrMOS dies can be implemented in other ways. Accordingly, other implementations are possible. Furthermore, although certain components of the DrMOS dies are depicted, DrMOS dies can include additional circuitry.

In the illustrated embodiment, an input control signal INa to the first DrMOS die 603a is provided to the logic 615a. The logic 615a controls driver signals to the high side driver 613a and the low side driver 614a, which control the high side power MOSFET 611a and low side power MOSFET 612a, respectively. The high side power MOSFET 611a and low side power MOSFET 612a are coupled to a first terminal VSWₐ of the inductor 608a to form a half bridge circuit of a switching regulator, such as a buck converter. The MOSFETs 611a/612a are switched on and off to control a current provided to the inductor 608a. A second terminal Voutₐ of the inductor 608a electrically connects to a load on a customer circuit board.

With continuing reference to FIG. 9, an input control signal INb to the second DrMOS die 603b is provided to the logic 615b. The logic 615b controls driver signals to the high side driver 613b and the low side driver 614b, which control the high side power MOSFET 611b and low side power MOSFET 612b, respectively. The high side power MOSFET 611b and low side power MOSFET 612b are coupled to a first terminal VSW_{b} of the inductor 608b and are switched on and off to control a current provided to the inductor 608b. A second terminal Vout_{b} of the inductor 608b electrically connects to a load on a customer circuit board.

In the illustrated embodiment, an input control signal INc to the third DrMOS die 603c is provided to the logic 615c. The logic 615c controls driver signals to the high side driver 613c and the low side driver 614c, which control the high side power MOSFET 611c and low side power MOSFET 612c, respectively. The high side power MOSFET 611c and low side power MOSFET 612c are coupled to a first terminal VSW_{c} of the inductor 608c to form a half bridge circuit of a switching regulator, such as a buck converter. The MOSFETs 611c/612c are switched on and off to control a current provided to the inductor 608c. A second terminal Vout_{c} of the inductor 608c electrically connects to a load on a customer circuit board.

With continuing reference to FIG. 9, an input control signal INd to the fourth DrMOS die 603d is provided to the logic 615d. The logic 615d controls driver signals to the high side driver 613d and the low side driver 614d, which control the high side power MOSFET 611d and low side power MOSFET 612d, respectively. The high side power MOSFET 611d and low side power MOSFET 612d are coupled to a first terminal VSW_{d} of the inductor 608d and are switched on and off to control a current provided to the inductor 608d. A second terminal Vout_{d} of the inductor 608d electrically connects to a load on a customer circuit board.

In certain implementations, a controller die (not shown in FIG. 9), generates the input signals INa/INb/INc/INd according to a desired control scheme, such as pulse width modulation (PWM).

### Applications

Devices employing the above-described schemes can be implemented into various electronic devices in a wide range of applications including, but not limited to, datacenters, electrical vehicles, energy storage, robots, bus converters, high current distributed power systems, and/or telecom systems. Thus, examples of electronic devices that can be implemented with the power modules herein include, but are not limited to, communication systems, consumer electronics products, electronic test equipment, communication infrastructure, servers, automobiles, etc.

In one example, the power module is used in datacenters to power graphic processing units (GPUs) for artificial intelligence (AI) applications, and the power module serves to shrink the size of the datacenter and save more energy. In another example, the power module is used in a power supply for an electrical vehicle to drive controllers and/or power switches. In a further example, the power module is used in a power supply for an energy storage system. In a further example, the power module is used in a robot to drive controllers and/or power switches.

### Conclusion

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. Accordingly, the scope of the present invention is defined only by reference to the appended claims.

Although the claims presented here are in single dependency format for filing at the USPTO, it is to be understood that any claim may depend on any preceding claim of the same type except when that is clearly not technically feasible.

What is claimed is:

1. A power module comprising:
a main circuit board;
an inductor component attached to the main circuit board; and
two or more power regulation circuit boards each attached to a different side of the inductor component and extending substantially perpendicular to the main circuit board to provide vertical power flow, wherein each power regulation circuit board includes at least one power semiconductor die.

2. The power module of claim 1, wherein the inductor component includes at least two inductors formed in a dielectric body, wherein each power semiconductor die regulates a current through one or more inductors of the inductor component.

3. The power module of claim 1, wherein the two or more power regulation circuit boards include a first power regulation circuit board attached to a first side of the inductor component and a second power regulation circuit board attached to a second side of the inductor component opposite the first side.

4. The power module of claim 3 wherein the two or more power regulation circuit boards further include a third power regulation circuit board attached to a third side of the inductor component and a fourth power regulation circuit board attached to a fourth side of the inductor component opposite the third side.

5. The power module of claim 1 wherein the main circuit board is attached to a bottom surface of the inductor component, the power module further including a thermal cooling structure attached to a top surface of the inductor component.

6. The power module of claim 5 wherein the thermal cooling structure includes a first side plate thermally contacting the at least one power semiconductor die of the first power regulation circuit board and a second side plate thermally contacting the at least one power semiconductor die of the second power regulation circuit board.

7. The power module of claim 5 wherein the thermal cooling structure includes heat fins extending away from the inductor component.

8. The power module of claim 5 wherein the thermal cooling structure includes side plates on each side of the inductor component.

9. The power module of claim 1 wherein the inductor component is attached to a top surface of the main circuit board, the main circuit board further including a pinout on a bottom surface opposite the top surface.

10. The power module of claim 1, wherein the two or more power regulation circuit boards each include an edge connection to the main circuit board, wherein no side pins for vertical interconnect external to the power module are present along a side of the power module.

11. The power module of claim 1, wherein the inductor component includes a first inductor, a second inductor, a third inductor, and a fourth inductor each formed in a dielectric body, wherein the two or more power regulation circuit boards including a first power regulation board including a first power semiconductor die configured to regulate a current through the first inductor and a second power semiconductor die configured to regulate a current through the second inductor, the two or more power regulation circuit boards further including a second power regulation board including a third power semiconductor die configured to regulate a current through the third inductor and a fourth power semiconductor die configured to regulate a current through the fourth inductor.

12. A power regulation system comprising:
a customer circuit board; and
a power module attached to the customer circuit board, the power module comprising:
a main circuit board attached to the customer circuit board;
an inductor component attached to the main circuit board opposite the customer circuit board; and
two or more power regulation circuit boards each attached to a different side of the inductor component and extending substantially perpendicular to the main circuit board to provide vertical power flow, wherein each power regulation circuit board includes at least one power semiconductor die.

13. The power regulation system of claim 12, wherein the inductor component includes at least two inductors formed in a dielectric body, wherein each power semiconductor die regulates a current through one or more inductors of the inductor component.

14. The power regulation system of claim 12, wherein the two or more power regulation circuit boards include a first power regulation circuit board attached to a first side of the inductor component and a second power regulation circuit board attached to a second side of the inductor component opposite the first side.

15. The power regulation system of claim 14, wherein the two or more power regulation circuit boards further include a third power regulation circuit board attached to a third side of the inductor component and a fourth power regulation circuit board attached to a fourth side of the inductor component opposite the third side.

16. The power regulation system of claim 12, wherein the main circuit board is attached to a bottom surface of the inductor component, the power module further including a thermal cooling structure attached to a top surface of the inductor component.

17. A method of power module assembly, the method comprising:
attaching a first power regulation circuit board to a first side of an inductor component;
attaching a second power regulation circuit board to a second side of the inductor component, the first power regulation circuit board and the second power regulation circuit board each including at least one power semiconductor die; and
attaching the inductor component including the first power regulation circuit board and the second power regulation circuit board to a main circuit board to form a power module, the first power regulation circuit board and the second power regulation circuit board extending substantially perpendicular to the main circuit board to provide vertical power flow.

18. The method of claim 17, further comprising attaching the first power regulation circuit board to a first side of the inductor component and attaching the second power regulation circuit board to a second side of the inductor component opposite the first side.

19. The method of claim 18, further comprising attaching a third power regulation circuit board to a third side of the inductor component and attaching a fourth power regulation circuit board to a fourth side of the inductor component opposite the second side.

20. The method of claim 17, further comprising attaching a thermal cooling structure to the inductor component opposite the main circuit board.
